(19) United States
(12) Patent Application Publication
(10) Pub. No.: US 2010/0317194 A1
(43) Pub. Date: Dec. 16, 2010

(54) METHOD FOR FABRICATING OPENING

(75) Inventors: Pin-Yuan Su, Taoyuan County (TW); Shu-Hao Hsu, Yunlin County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/483,255

(22) Filed: Jun. 12, 2009

(51) Int. Cl. H01L 21/302; G03F 7/20

(52) U.S. Cl. 438/694; 430/316; 430/312; 257/E21.214

(57) ABSTRACT

A method for fabricating openings is provided. A dielectric layer is formed on a substrate, and a first patterned mask layer is formed on the dielectric layer along a first direction. A second patterned mask layer is then formed on the dielectric layer along a second direction which intersects with the first direction. A portion of the dielectric layer is removed using the first patterned mask layer and the second patterned mask layer as a mask so as to from the openings. The dielectric layer, the first patterned mask layer and the second patterned mask layer have different etching selectivities.

### BACKGROUND OF THE INVENTION

1. Field of the Invention

The present invention generally relates to a semiconductor process, and in particular, to a method for fabricating an opening.

2. Description of Related Art

Along with rapid progress of semiconductor technology, the dimensions of semiconductor devices are reduced and the integrity thereof is promoted continuously to further advance the operating speed and performance of the integrated circuit. As for memory components having the capacitors, the size reducing means the available space used for fabricating the capacitors become smaller and smaller, as the demand for device integrity is raised. The capacitors are indispensable components in an integrated circuit. In the design and process of the capacitors, capacitance and disposal area of the capacitors must be taken into account. Therefore, it is an important topic in the integrated circuit design to propose a capacitor structure having a high integrity and high capacitance in the current integrated circuit process, so as to increase the effective surface area and improve the capacitor performance when the area occupied by the capacitor is gradually reduced.

Generally, the capacitors can be classified into stacked capacitors and deep trench capacitors in accordance with the position where the capacitors are formed. The stacked capacitors are formed on the silicon substrate directly, while the deep trench capacitors are formed inside the silicon substrate. In order to reach the enlarged effective surface area, containers for accommodating the stacked capacitors should be designed in square contours, rather than circle contours of the conventional process. However, the line width and the pattern profile of the photoresist layer can not meet the above-mentioned demands due to the limitation in the current lithography process. Thereby, the increase in the contact surface area of the capacitors is quite restricted.

There are other methods for increasing the charge storage capacity of capacitors, such as a use of positive photoresist and negative photoresist to fabricate a desired pattern. The shape of the opening formed by the positive and negative photoresist, however, cannot be square due to the chemical reaction of acid utilized in the lithography process. Moreover, the opening to be formed usually suffers from a serious potato shape issue after a hard mask is etched. Hence, how to make the capacitors with sufficient capacity and good performance has to be considered in the recent semiconductor technology.

### SUMMARY OF THE INVENTION

Accordingly, the present invention is directed to a method for fabricating openings, in which the formation of the opening can be well controlled to obtain a desired profile.

The method for fabricating the openings of the present invention is described as follows. A dielectric layer is formed on a substrate, and a first patterned mask layer is formed on the dielectric layer along a first direction. A second patterned mask layer is then formed on the dielectric layer along a second direction which intersects with the first direction. A portion of the dielectric layer is removed using the first patterned mask layer and the second patterned mask layer as a mask so as to from the openings. The dielectric layer, the first patterned mask layer and the second patterned mask layer have different etching selectivities.

According to an embodiment of the present invention, a method for forming the first patterned mask layer may include following steps. A first mask layer and a first patterned photoresist layer are formed in sequence on the dielectric layer. A portion of the first mask layer is removed using the first patterned photoresist layer as a mask, so as to form the first patterned mask layer with striped patterns. The first patterned photoresist layer is then removed.

According to an embodiment of the present invention, a method for forming the second patterned mask layer may include following steps. A second mask layer is formed on the dielectric layer and covers the first patterned mask layer. The second mask layer is then planarized until exposing the first patterned mask layer. A second patterned photoresist layer is formed on the second mask layer. A portion of the second mask layer is removed using the second patterned photoresist layer as a mask, so as to form the second patterned mask layer with striped patterns which intersects with the first patterned mask layer. The second patterned photoresist layer is then removed. An anti-reflection layer is further formed between the second mask layer and the second patterned photoresist layer, for example.

According to an embodiment of the present invention, before the second patterned mask layer is formed, a trimming process is further performed to the first patterned mask layer. The trimming process may include an isotropic etching.

According to an embodiment of the present invention, before a portion of the dielectric layer is removed, a trimming process is further performed to the second patterned mask layer. The trimming process may include an isotropic etching.

According to an embodiment of the present invention, the first direction and the second direction are substantially perpendicular to each other. Each opening, for example, has a rectangular shape from a top view of the openings. The first direction may intersect with the second direction orthogonally.

According to an embodiment of the present invention, a material of the first patterned mask layer can be polysilicon. A material of the second patterned mask layer can be carbon. A material of the dielectric layer can be silicon oxide.

According to an embodiment of the present invention, the substrate may include a semiconductor substrate or a conductive area.

According to an embodiment of the present invention, each of the openings is a container of a capacitor or a contact hole.

As mentioned above, the method for fabricating the opening is implemented by forming the intersecting patterned mask layers that are then used as a mask for forming the openings in the dielectric layer. The openings have a rectangular or square contour due to the substantially perpendicular deployment of the first and second patterned mask layers. Thus, the capacitors or the plugs formed in the openings can have improved capacitance or reduced contact resistance, respectively.

In order to make the aforementioned and other features of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-6A depict, in a top view, a method for fabricating an opening according to an embodiment of the present invention.

FIGS. 1B-6B are schematic cross-sectional diagrams of the structure shown in FIGS. 1A-6A along line I-I′, respectively.

FIGS. 1C-6C are schematic cross-sectional diagram of the structure shown in FIGS. 1A-6A along line II-II′, respectively.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

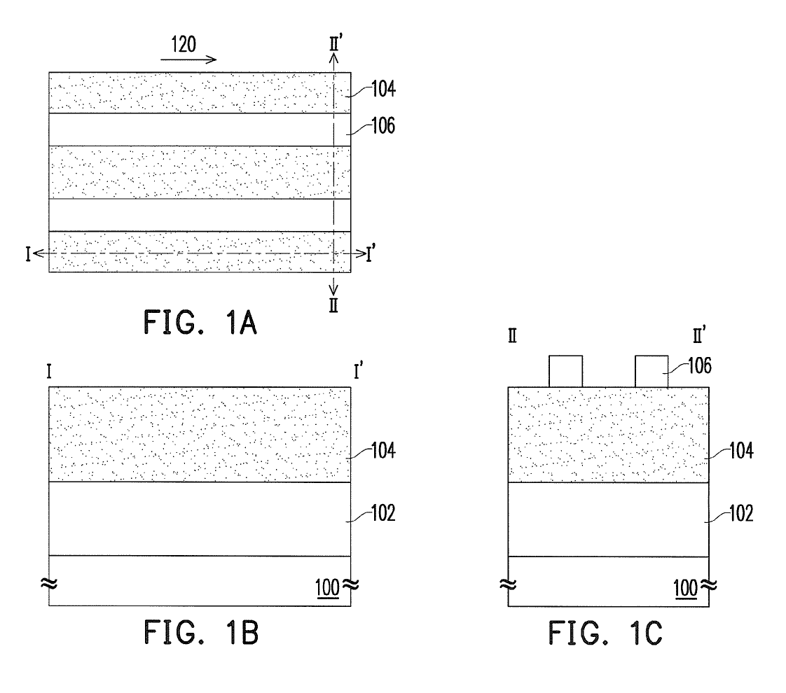

FIGS. 1A-6A depict, in a top view, a method for fabricating an opening according to an embodiment of the present invention. FIGS. 1B-6B are schematic cross-sectional diagrams of the structure shown in FIGS. 1A-6A along line I-I′, respectively. FIGS. 1C-6C are schematic cross-sectional diagram of the structure shown in FIGS. 1A-6A along line II-II′, respectively.

Referring to FIGS. 1A, 1B and 1C concurrently, a substrate 100 is provided, which may be a semiconductor substrate, e.g. P-type or N-type silicon substrate. In an embodiment, the substrate 100 may further include a plurality of devices or conductive areas formed thereon. A dielectric layer 102 and a first mask layer 104 are formed on the substrate 100 sequentially. The dielectric layer 102 and the first mask layer 104, for example, have different etching selectivities. In an embodiment, a material of the dielectric layer 102 is silicon oxide, and a material of the first mask layer 104 is polysilicon. A first patterned photoresist layer 106 is then formed on the first mask layer 104. The first patterned photoresist layer 106, for example, has a plurality of striped patterns along a first direction 120.

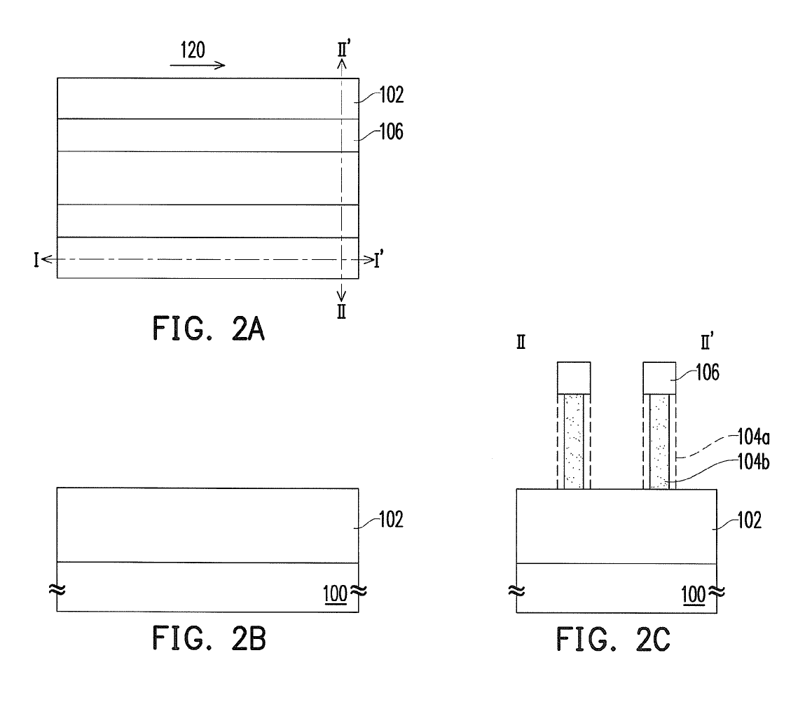

Referring to FIGS. 2A, 2B and 2C concurrently, a portion of the first mask layer 104 is removed using the first patterned photoresist layer 106 as a mask to form a first patterned mask layer 104a, such that a portion of the dielectric layer 102 is exposed. The first patterned mask layer 104a may be patterned in the form of striped patterns which disposed along the first direction 120. A method for forming the first patterned mask layer 104a can be a dry etching process. In an embodiment, a trimming process can be further conducted to the first patterned mask layer 104a, so as to form a trimmed first patterned mask layer 104b. The trimming process can be carried out by an isotropic wet etching using DHF and NH₄OH/H₂O as etchants. For example, the critical dimension (CD) of the untrimmed first patterned mask layer 104a may be 60 nm, and the CD of the trimmed first patterned mask layer 104b may be 30 nm.

It should be noted that the cross-sectional profiles of the first patterned mask layer 104b in the foregoing example are provided for illustration purposes, and is not construed as limiting the scope of the present invention. It is appreciated by persons skilled in the art that the contour of the first patterned mask layer 104b depicted in FIG. 2C can be etched in the form of a taper structure, that is to say, a cross-section with a larger upper surface or with a larger lower surface.

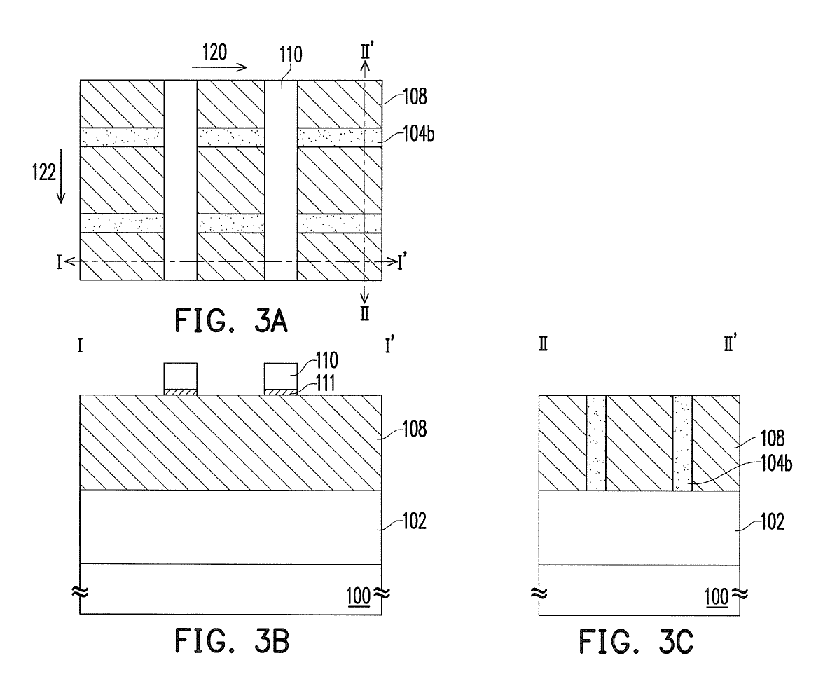

Referring to FIGS. 3A, 3B and 3C, the first patterned photoresist layer 106 is then removed. A second mask layer 108 is stacked on the dielectric layer 102 and covers the exposed surface of the dielectric layer 102. The formation of the second mask layer 108 can be implemented by depositing a second mask material layer (not shown) which covers the first patterned mask layer 104b, and then planarizing the second mask material layer using the first patterned mask layer 104b as a stop layer. A method for planarizing the second mask material layer is, for example, a chemical mechanical polishing (CMP) process or an etching back process. The second mask layer 108, the dielectric layer 102 and the first patterned mask layer 104b, for example, have different etching selectivities. A material of the second mask layer 108 can be carbon. Afterwards, a second patterned photoresist layer 110 is formed on the second mask layer 108. The second patterned photoresist layer 110, for example, has a plurality of striped patterns along a second direction 122, wherein the first direction 120 and the second direction 122 intersect with each other. The first direction 120 and the second direction 122 may be substantially perpendicular to each other. In an embodiment, an anti-reflection layer 111 may be formed between the second patterned photoresist layer 110 and the second mask layer 108.

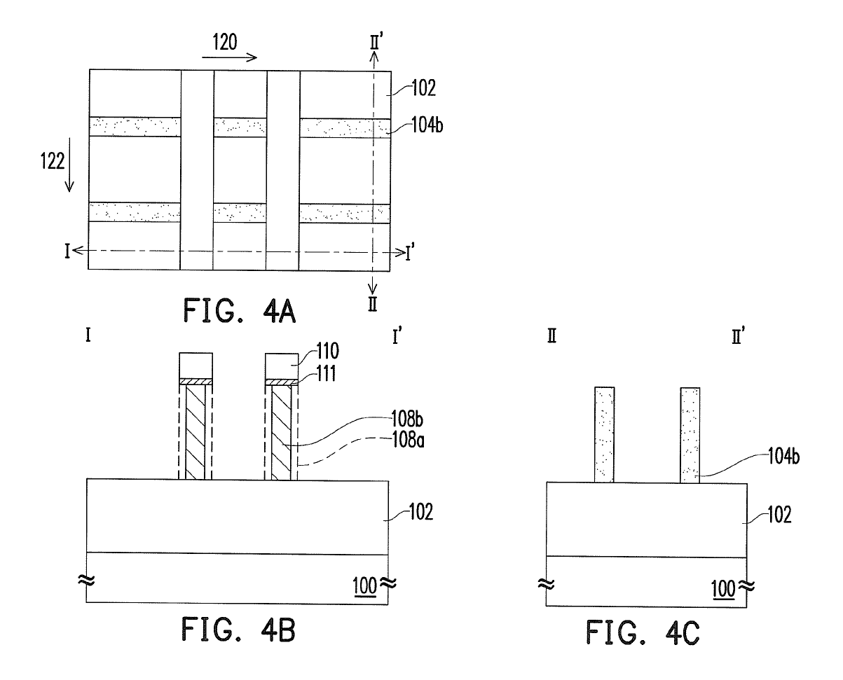

Referring to FIGS. 4A, 4B and 4C concurrently, removing a portion of the second mask layer 108 using the second patterned photoresist layer 110 as a mask, so as to form a second patterned mask layer 108a. A portion of the dielectric layer 102 is exposed, for example. The second patterned mask layer 108a may be patterned in the form of striped patterns which disposed along the second direction 122. Therefore, the first patterned mask layer 104b intersects the second patterned mask layer 108a. A method for forming the second patterned mask layer 108a can be a dry etching process. In an embodiment, a trimming process can be further conducted to the second patterned mask layer 108a, so as to form a trimmed second patterned mask layer 108b. The trimming process can be carried out by an isotropic etching using SO₂ and O₂ as reactant gases. The critical dimension (CD) of the untrimmed second patterned mask layer 108a is 60 nm, and the CD of the trimmed second patterned mask layer 108b is 30 nm, for example.

Likewise, it should be noted that the cross-sectional profiles of the second patterned mask layer 108b in the foregoing example are provided for illustration purposes, and is not construed as limiting the scope of the present invention. It is appreciated by persons skilled in the art that the contour of the second patterned mask layer 108b depicted in FIG. 4B can be etched in the form of a taper structure, that is to say, a cross-section with a larger upper surface or with a larger lower surface.

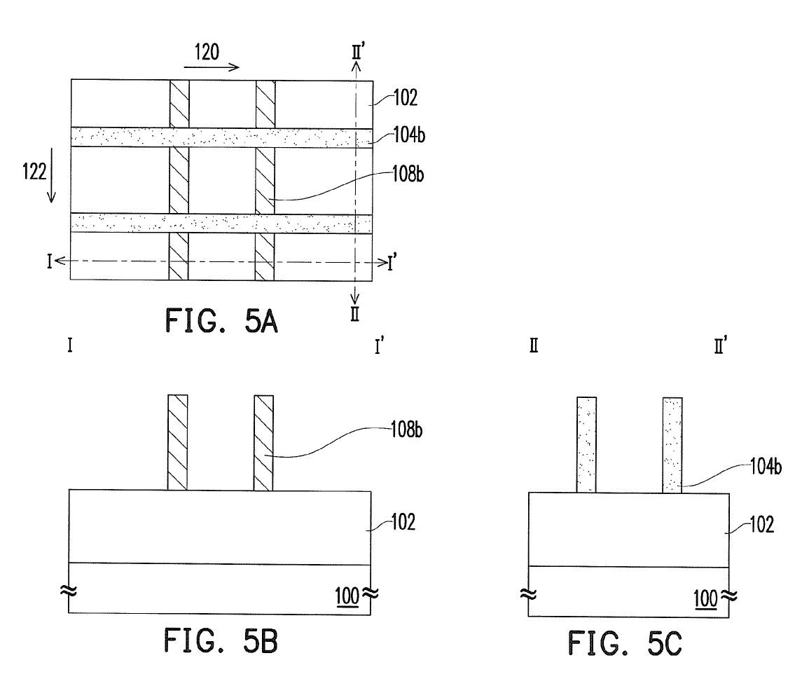

Referring to FIGS. 5A, 5B and 5C, the second patterned photoresist layer 110 is then removed. Accordingly, the first patterned mask layer 104b lies in striped patterns along the first direction 120 on the dielectric layer 102, while the second patterned mask layer 108b lies in striped patterns along the second direction 122 on the dielectric layer 102. The first patterned mask layer 104b may intersect the second patterned mask layer 108b perpendicularly.

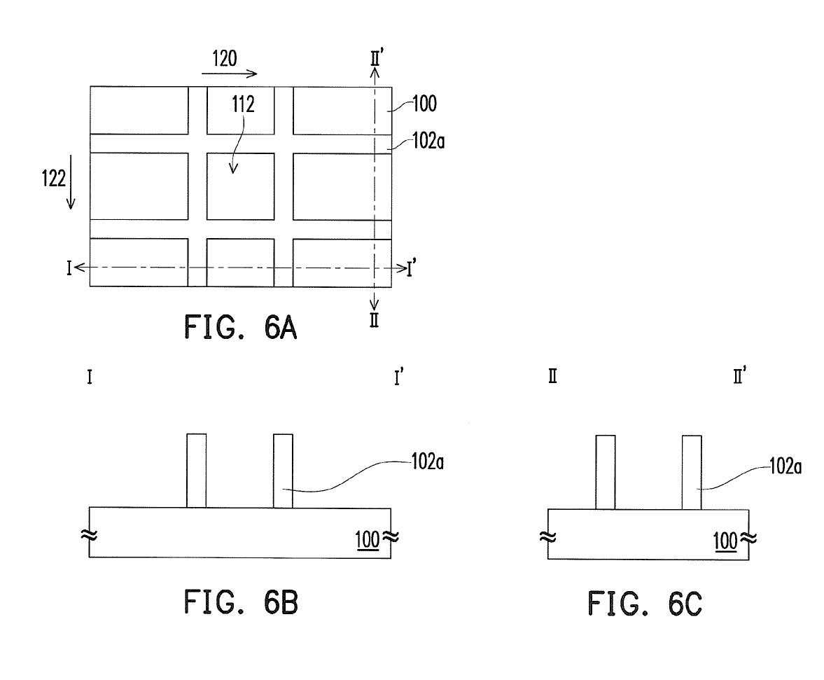

Referring to FIGS. 6A, 6B and 6C concurrently, a portion of the dielectric layer 102 is removed using the first patterned mask layer 104b and the second patterned mask layer 108b as a mask, so as to expose partial surface of the uncovered substrate 100. Accordingly, a plurality of openings 112 is formed at the position defined by the remaining dielectric layer 102a. The removal of a portion of the dielectric layer 102 can be accomplished by a dry etching process. Thereafter, the first patterned mask layer 104b and the second patterned mask layer 108b are removed.

Since the first patterned mask layer 104b and the second patterned mask layer 108b are substantially perpendicular to each other, the openings 112 which is defined thereby can be rectangular in a top view. In an embodiment, each opening 112 may have a square contour. The rectangular or square openings can have an increased volume and an enlarged contact area. Besides, the formation of the openings 112 can be well controlled by line widths of the first patterned mask layer 104b and the second patterned mask layer 108b, and therefore higher resolution is obtained. What's more, the contour of the openings 112 is not limited to that shown in the embodiment illustrated by FIG. 6A, alteration of the contour is allowed in this invention which relies on modification of the patterned mask layers.

In an embodiment, when the substrate 100 is a semiconductor substrate, the openings 112 in which the surface of the semiconductor substrate is exposed can be utilized as a container for forming capacitors therein. The capacitors formed in the rectangular or square container can be equipped with enhanced capacitance due to the increased surface area. In addition, the fabrication methods and forming sequences of the capacitors, i.e. the formation of bottom electrode, a capacitor dielectric layer and a top electrode, are well appreciated by persons skilled in the art, and thus, the detailed descriptions thereof are not described herein.

In another embodiment, when the surface of the substrate 100 include the devices or conductive areas formed thereon, the openings 112 can be utilized as a contact holes for forming conductive plugs therein. The conductive plugs formed in the rectangular or square contact holes have decreased contact resistance, for example. Likewise, the fabrication methods of the foregoing plugs should be well appreciated by persons skilled in the art, and thus, the detailed descriptions thereof are not described herein.

In view of the above, the method for fabricating the openings according to an embodiment of the present invention is achieved by the formation of the stripe-like mask layers intersecting with each other. The profiles of the openings defined by the striped mask layers are prone to be substantially rectangular or square, thereby facilitating increases in the volume and the contact area. Hence, the capacitors formed in the rectangular or square openings can have improved capacitance, and the contact plugs formed in the rectangular or square openings can have reduced contact resistance.

Moreover, the method for fabricating the openings in the present invention relies on a simple patterning process through the modification of the patterned mask layers, so as to easily be incorporated into the current process. Hence, not only the process is simplified without raising the cost, the desired profile of the openings can be obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating openings, comprising:
forming a dielectric layer on a substrate;
forming a first patterned mask layer on the dielectric layer along a first direction;
forming a second patterned mask layer on the dielectric layer along a second direction which intersects with the first direction; and
removing a portion of the dielectric layer using the first patterned mask layer and the second patterned mask layer as a mask so as to from the openings,
wherein the dielectric layer, the first patterned mask layer and the second patterned mask layer have different etching selectivities.

2. The method according to claim 1, wherein a method for forming the first patterned mask layer comprises:
forming a first mask layer on the dielectric layer;
forming a first patterned photoresist layer on the first mask layer;
removing a portion of the first mask layer using the first patterned photoresist layer as a mask, so as to form the first patterned mask layer with striped patterns; and
removing the first patterned photoresist layer.

3. The method according to claim 1, wherein a method for forming the second patterned mask layer comprises:
forming a second mask layer on the dielectric layer and covering the first patterned mask layer;
planarizing the second mask layer until exposing the first patterned mask layer;
forming a second patterned photoresist layer on the second mask layer;
removing a portion of the second mask layer using the second patterned photoresist layer as a mask, so as to form the second patterned mask layer with striped patterns which intersects with the first patterned mask layer; and
removing the second patterned photoresist layer.

4. The method according to claim 3, further comprising forming an anti-reflection layer between the second mask layer and the second patterned photoresist layer.

5. The method according to claim 1, before the second patterned mask layer is formed, further comprising performing a trimming process to the first patterned mask layer.

6. The method according to claim 5, wherein the trimming process comprises an isotropic etching.

7. The method according to claim 1, before a portion of the dielectric layer is removed, further comprising performing a trimming process to the second patterned mask layer.

8. The method according to claim 7, wherein the trimming process comprises an isotropic etching.

9. The method according to claim 1, wherein the first direction and the second direction are substantially perpendicular to each other.

10. The method according to claim 9, wherein each opening has a rectangular shape from a top view of the openings.

11. The method according to claim 1, wherein the first patterned mask layer comprises polysilicon.

12. The method according to claim 1, wherein the second patterned mask layer comprises carbon.

13. The method according to claim 1, wherein the dielectric layer comprises silicon oxide.

14. The method according to claim 1, wherein the substrate comprises a semiconductor substrate or a conductive area.

15. The method according to claim 1, wherein each of the openings is a container of a capacitor or a contact hole.

16. The method according to claim 10, wherein the first direction intersects with the second direction orthogonally.
